(19) United States
(12) Patent Application Publication
(10) Pub. No.: US 2026/0144140 A1
(43) Pub. Date: May 21, 2026

(54) ELECTRO-OPTICAL DEVICE WITH AN ELECTRONIC INTEGRATED CIRCUIT AND PHOTONIC CHIPLETS

(71) Applicant: Cisco Technology, Inc., San Jose, CA (US)

(72) Inventors: Norbert SCHLEPPLE, Macungie, PA (US); Hiren D. THACKER, San Diego, CA (US); Ravi S. TUMMIDI, Breinigsville, PA (US)

(21) Appl. No.: 18/949,829

(22) Filed: Nov. 15, 2024

(51) Int. Cl. H01L 25/16; G02B 6/12; H01L 23/00; H01L 23/48; H10B 80/00

(52) U.S. Cl. CPC H10W 90/00; G02B 6/12004; H10B 80/00; H10W 20/20; H10W 90/792

(57) ABSTRACT

An electro-optical device is disclosed. In one aspect, an electro-optical device includes an electrical integrated circuit (EIC) and a photonic integrated circuit (PIC) chiplet bonded face-to-face with the EIC. The PIC chiplet is smaller in size than the EIC. The electro-optical device also includes a fiber array unit (FAU) having an optical fiber optically coupled with the PIC chiplet. Methods of fabricating electro-optical devices are also provided.

### TECHNICAL FIELD

Embodiments presented in this disclosure generally relate to electro-optical devices.

### BACKGROUND

Many electro-optical devices used in optical transceivers, co-packaged optics (CPO), near packaged optics (NPO), etc. apply a flip-chip (FC) chip-on-chip (CoC) architecture to keep distances short between an electrical integrated circuit (EIC) and a photonic integrated circuit (PIC) of the device. Specifically, the CoC architecture is arranged so that driver-to-modulator (EIC-to-PIC) and photodetector-to-transimpedance amplifier (PIC-to-EIC) electrical distances are kept short in an attempt to keep signal integrity (SI) high. The EIC is smaller than the PIC to minimize the die size because the EIC is normally fabricated in a more expensive process node. The result is that the PIC can be excessively larger than the sum of the optical elements integral to the PIC. The relatively large PIC die can be a significant contributor to the overall cost of an electro-optical device and can reduce design freedom.

Moreover, with the desire to increase bandwidth and computing efficiency within artificial intelligence and machine learning (AI/ML) applications as well as in high-performance computing (HPC) systems, certain electro-optical solutions have been introduced in an attempt to provide bandwidth disaggregation and to reduce latency, power, and cost of the systems arranged to execute such applications. However, such systems typically have excessively large PICs and thus are relatively large packages. Moreover, such systems can also have less than desirable SI and can have power dissipation penalties due to their architectures.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIGS. 1A and 1B are a schematic top plan view and side cross-sectional view of an electro-optical device according to one or more aspects of the present disclosure.

FIGS. 2A and 2B are a schematic top plan view and side cross-sectional view of an electro-optical device according to one or more aspects of the present disclosure.

FIGS. 3A and 3B are a schematic top plan view and side cross-sectional view of an electro-optical device according to one or more aspects of the present disclosure.

FIGS. 4A and 4B are a schematic top plan view and side cross-sectional view of an electro-optical device according to one or more aspects of the present disclosure.

FIGS. 5A and 5B are a schematic top plan view and side cross-sectional view of an electro-optical device according to one or more aspects of the present disclosure.

FIG. 5C is a schematic side cross-sectional view of the electro-optical device of FIGS. 5A and 5B with a filler, according to one or more aspects of the present disclosure.

FIG. 6 is a schematic side cross-sectional view of an electro-optical device according to one or more aspects of the present disclosure.

FIG. 7 is a schematic side cross-sectional view of an electro-optical device according to one or more aspects of the present disclosure.

FIGS. 8A-8F provide a flow diagram for a method of fabricating an electro-optical device according to one or more aspects of the present disclosure.

FIGS. 9A-9E provide a flow diagram for a method of fabricating an electro-optical device according to one or more aspects of the present disclosure.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### OVERVIEW

In one aspect, an electro-optical device is provided. The electro-optical device includes an electrical integrated circuit (EIC) and a photonic integrated circuit (PIC) chiplet bonded face-to-face with the EIC. The PIC chiplet is smaller in size than the EIC. The electro-optical device also includes a fiber array unit (FAU) having an optical fiber optically coupled with the PIC chiplet.

In a further aspect, an electro-optical device is provided. The electro-optical device includes an electrical integrated circuit (EIC) and a photonic integrated circuit (PIC) chiplet bonded face-to-face with the EIC. The PIC chiplet is smaller in size than the EIC and has an on-chip network. The on-chip network includes integrated lasers arranged to provide light inputs to a plurality of interconnected nodes and integrated photodetectors arranged to receive light outputs from the plurality of interconnected nodes.

In yet a further aspect, a method of fabricating an electro-optical device is provided. The method includes bonding photonic integrated circuit (PIC) chiplets to an electronic integrated circuit (EIC) wafer; machining the PIC chiplets to reduce a thickness thereof; and singulating the EIC wafer to form singulated units, with each of the singulated units having one or more of the PIC chiplets and a portion of the EIC wafer.

In another aspect, a method of forming an electro-optical device is provided. The method includes bonding photonic integrated circuit (PIC) chiplets to an electronic integrated circuit (EIC) wafer; forming interconnects on the EIC wafer, with the interconnects being juxtaposed with the PIC chiplets; backfilling the interconnects with a filler; machining the PIC chiplets and backfilled interconnects; and singulating the EIC wafer to form singulated units, with each of the singulated units having one or more of the PIC chiplets, at least one of the backfilled interconnects, and a portion of the EIC wafer.

In yet another aspect, a method of forming an electro-optical device is provided. The method includes bonding photonic integrated circuit (PIC) chiplets to a first side of an electronic integrated circuit (EIC) wafer, the EIC wafer having through-silicon vias (TSVs); reducing a thickness of the PIC chiplets; machining a second side of the EIC to reveal the TSVs, the second side being opposite the first side; and singulating the EIC wafer to form singulated units, with each of the singulated units having one or more of the PIC chiplets, at least one of the TSVs, and a portion of the EIC wafer.

### EXAMPLE EMBODIMENTS

Electro-optical devices disclosed herein can include a hybrid integration of one or more photonic integrated circuit (PIC) chiplets, or PIC chiplets, with a larger electronic integrated circuit (EIC), which, in essence, can add optical input-output (I/O) functionality to an EIC. The electro-optical devices of the present disclosure can be useful in a number of applications, such as for optical transceivers, in high-performance “X” processor units (XPU) applications, and in tensor processing unit (TPU) applications, among others. In optical transceiver applications, for instance, the electro-optical devices of the present disclosure can enable a significant size reduction of the PIC, which can reduce costs and enable greater package design freedom. The intimate integration of the PIC chiplet(s) with the EIC can provide both enhanced signal integrity (SI) and power integrity (PI). In one or more examples, the intimate integration can be provided by face-to-face bonding of the PIC chiplet to the EIC, such as by a metal-to-metal, oxide-to-oxide hybrid bond. In high performance XPU applications, the electro-optical devices of the present disclosure can provide optical ports that mitigate I/O bandwidth bottlenecks, and can enable bandwidth disaggregation and optical data co-processing entirely within the chip package. In TPU applications, which can be used for training and implementing neural networks, including large language models (LLM), the electro-optical devices of the present disclosure can enable a “hybrid TPU”. The hybrid TPU can provide power, performance, and latency benefits by partially offloading tasks to optical blocks on one more PIC chiplets bonded to the TPU. For instance, multiply-accumulate (MAC) operations can be offloaded to one more optically self-sufficient PIC chiplets that can perform the MAC operations in the optical domain.

In addition, the electro-optical devices of the present disclosure can enable edge coupling for fiber array units (FAUs), surface coupling for FAUs, multiple optical FAU edge-couplings, and optically-enabled substrates for onboard or offboard optical routing. Further, the present disclosure provides methods of fabrication of electro-optical devices having such architectures. Example electro-optical devices and method of fabrication are presented below.

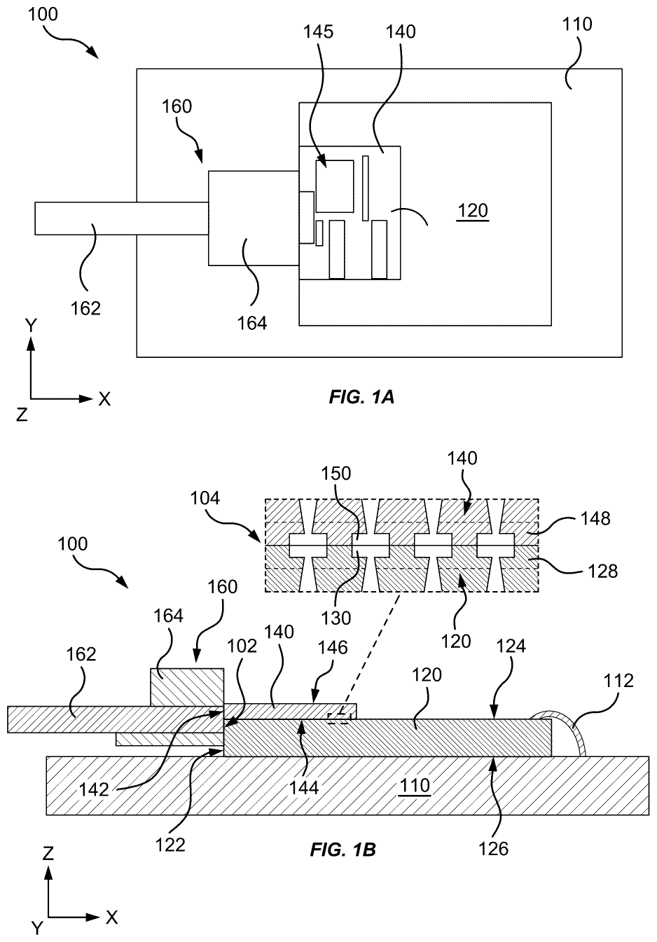

Turning now to the drawings, FIGS. 1A and 1B provide schematic views of an electro-optical device 100 according to one or more aspects of the present disclosure. FIG. 1A is a schematic top plan view and FIG. 1B is a schematic side cross-sectional view of the electro-optical device 100. The electro-optical device 100 can be used in optical transceiver applications, among others. For reference, the electro-optical device 100 defines an X-direction, a Y-direction, and a Z-direction, which are mutually perpendicular to one another. The X-direction can be a longitudinal direction, the Y-direction can be a lateral direction, and the Z-direction can be a vertical direction, for example.

As depicted in FIGS. 1A and 1B, the electro-optical device 100 includes a substrate 110 (e.g., a printed circuit board (PCB)), an electrical integrated circuit (EIC), or EIC 120, and a photonic integrated circuit (PIC) chiplet, or PIC chiplet 140, and a fiber array unit (FAU), or FAU 160. The FAU 160 has one or more optical fibers 162 and a holder 164 that holds and supports the optical fibers 162. In at least one example, the EIC 120 can be an application-specific integrated circuit (ASIC), e.g., for networking applications. In at least one example, the EIC 120 can be a high bandwidth memory device, or HBP device.

In one or more examples, the FAU 160 can be attached to a planar facet 102 provided in part by the PIC chiplet 140 and in part by the EIC 120, as shown in FIG. 1B. Particularly, the PIC chiplet 140 has a side face 142 that provides an optical coupling facet of the PIC chiplet 140. The side face 142, or edge face of the PIC chiplet 140, is coplanar with a side face 122 of the EIC 120. The side face 142 of the PIC chiplet 140 and the side face 122 of the EIC 120 collectively form the planar facet 102 to which the FAU 160 is attached. The optical fiber 162 is optically coupled with the PIC chiplet 140, and more specifically, optical components thereof. In this way, optical signals can travel between the optical fiber 162 and the optical components of the PIC chiplet 140. The optical fiber 162 can be a single mode fiber, for example.

In one or more examples, such as in the embodiment of FIGS. 1A and 1B, the PIC chiplet 140 can be sized to an extent necessary to hold optical blocks 145 (seven (7) optical blocks are shown in FIG. 1A) of the PIC chiplet 140. Example optical blocks can include receiver components (e.g., a photodetector), transmitter components (e.g., a modulator), optical multiplexer/demultiplexers (mux/demux), and spot size converters (SSC). Accordingly, in some aspects, the PIC chiplet 140 can be smaller in size than the EIC 120. Stated differently, the EIC 120 can have a larger footprint than the PIC chiplet 140. As shown in FIG. 1A, the PIC chiplet 140 has a shorter dimension along the X-direction than the EIC 120 and a short dimension along the Y-direction than the EIC 120. Accordingly, the PIC chiplet 140 has a smaller area than the EIC 120 as viewed along the Z-direction. In at least one example, the EIC 120 has an area that is at least two times greater than an area of the PIC chiplet 140, with the areas being measured in an XY plane, or rather, as viewed along the Z-direction as in FIG. 1A. The relatively small size of the PIC chiplet 140 can reduce costs and can enable enhanced signal and power integrity, as well as improved design freedom. In one or more examples, the optical blocks 145 each have an area, and wherein a total area of the PIC chiplet 140 is not more than twice a total optical block area that is a sum of the areas of the optical blocks 145, with the total area and the total optical block area both being measured in a direction perpendicular to a plane in which the PIC chiplet 140 is bonded face-to-face with the EIC 120. In FIG. 1A, the plane in which the PIC chiplet 140 is bonded face-to-face with the EIC 120 is the XY plane, and thus, the direction perpendicular to the plane in which the PIC chiplet 140 is bonded face-to-face with the EIC 120 is the Z-direction.

In one or more examples, the PIC chiplet 140, which can be formed of silicon on insulator (SOI), can be bonded face-to-face with the EIC 120. In the illustrated embodiment of FIGS. 1A and 1B, for instance, the PIC chiplet 140 is stacked on the EIC 120, and the PIC chiplet 140 is bonded face-to-face with the EIC 120. Particularly, the EIC 120 has an active side 124 arranged face up (e.g., facing in an upward direction along the Z-direction) and a back side 126 opposite the active side 124. The PIC chiplet 140 has an active side 144 arranged face down (e.g., facing in a downward direction along the Z-direction) and a back side 146 opposite the active side 144. The PIC chiplet 140 and the EIC 120 are bonded face-to-face with the active side 124 of the EIC 120 bonded to the active side 144 of the PIC chiplet 140. In this manner, electrical signals can travel between the EIC 120 and the PIC chiplet 140. For the embodiment of FIGS. 1A and 1B, the bonding faces of the EIC 120 and the PIC chiplet 140 are planar surfaces. Accordingly, the PIC chiplet 140 and the EIC 120 are bonded in a planar face-to-planar face manner, which can minimize the overall height of the electro-optical device 100. The substrate 110 can be wire bonded to the active side 124 of the EIC 120 by one or more wire bonds 112 so that electrical signals can travel between the EIC 120 and the substrate 110.

In one or more examples, the PIC chiplet and the EIC 120 can be bonded face-to-face with a hybrid bond 104, as shown in the close-up view in FIG. 1B. The hybrid bond 104 can be a metal-to-metal, oxide-to-oxide hybrid bond, for example. In some aspects, the hybrid bond 104 can be a copper-to-copper, oxide-to-oxide hybrid bond. The EIC 120 can include an oxide layer 128 and a plurality of metal pads 130. The metal pads 130 can be arranged in an array of rows and columns (e.g., in a rectangular array), with the metal pads 130 being spaced from one another along the X-direction and the Y-direction. Similarly, the PIC chiplet 140 can include an oxide layer 148 and a plurality of metal pads 150. The metal pads 150 can be arranged in an array of rows and columns (e.g., in a rectangular array), with the metal pads 150 being spaced from one another along the X-direction and the Y-direction. The metal pads 150 of the PIC chiplet 140 can be arranged complementary to the metal pads 130 of the EIC 120, e.g., so that metal pads align when the PIC chiplet 140 and the EIC 120 are bonded together.

During hybrid bonding, a metal-to-metal bond (e.g., a copper-to-copper bond) can be formed between the metal pads 130 of the EIC 120 and the metal pads 150 of the PIC chiplet 140, and an oxide-to-oxide bond can be formed between the oxide layer 128 of the EIC 120 and the oxide layer 148 of the PIC chiplet 140. The close-up view in FIG. 1B shows the metal pads 130 of the EIC 120 in bonded engagement with respective ones of the metal pads 150 of the PIC chiplet 140 and the oxide layer 128 of the EIC 120 in bonded engagement with the oxide layer 148 of the PIC chiplet 140, on both sides of the metal-to-metal bonds. Such a hybrid bond can provide coupling between the EIC 120 and the PIC chiplet 140 and can reduce device parasitics by reducing bond pad area and interconnect length, among other benefits. Further, the hybrid bond 104 creates a rigid structure that supports the relatively thin PIC chiplet 140 (the PIC chiplet 140 being relatively thin compared to the EIC 120.

In one or more other examples, the PIC chiplet 140 can be bonded to the EIC 120 using another technique, such as a thermocompression bonding process. In one or more other examples, the PIC chiplet 140 can be bonded to the EIC 120 using another technique, such as fine-pitch solder interconnect bonding process.

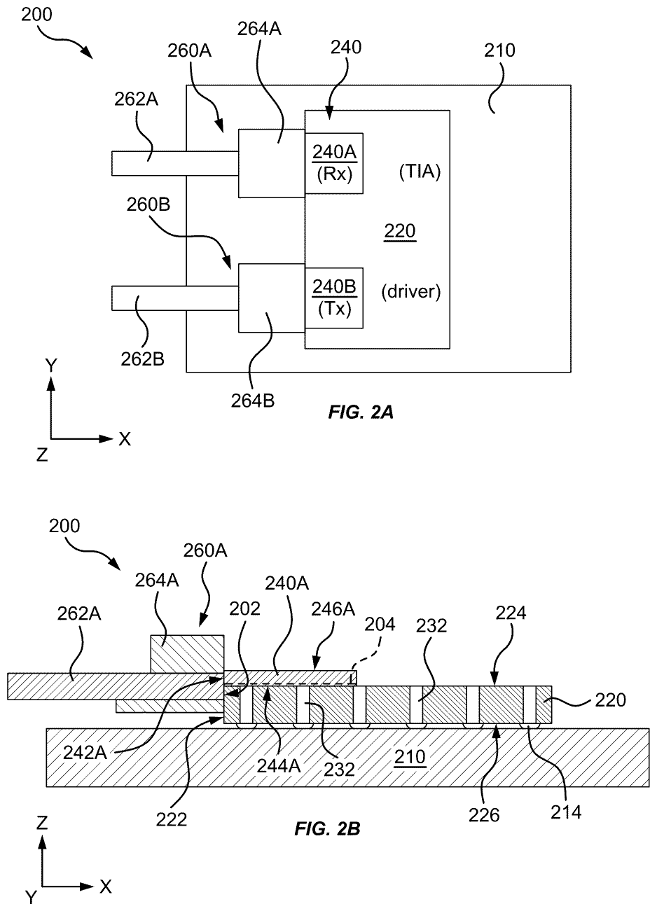

FIGS. 2A and 2B are schematic views of an electro-optical device 200 according to one or more aspects of the present disclosure. FIG. 2A is a schematic top plan view and FIG. 2B is a schematic side cross-sectional view of the electro-optical device 200. In FIGS. 2A and 2B, the electro-optical device 200 is configured for transceiver applications.

As depicted in FIGS. 2A and 2B, the electro-optical device 200 includes a substrate 210 (e.g., a PCB), an EIC 220, and PIC chiplets 240, including a first PIC chiplet 240A and a second PIC chiplet 240B (collectively the PIC chiplets 240). The electro-optical device 200 also includes FAUs, including a first FAU 260A and a second FAU 260B.

The first FAU 260A is attached (e.g., edge coupled) to a planar facet 202 provided in part by the first PIC chiplet 240A and in part by the EIC 220, as shown in FIG. 2B. Particularly, the first PIC chiplet 240A has a side face 242A that provides an optical coupling facet of the first PIC chiplet 240A. The side face 242A of the first PIC chiplet 240A is coplanar with a side face 222 of the EIC 220. The side face 242A of the first PIC chiplet 240A and the side face 222 of the EIC 220 collectively form the planar facet 202 to which the first FAU 260A is attached. The first FAU 260A has one or more first optical fibers 262A and a first holder 264A that holds and supports the first optical fibers 262A. The first optical fibers 262A is/are optically coupled with the first PIC chiplet 240A, and more specifically, optical components thereof. In this way, optical signals can traverse between the first optical fibers 262A and the optical components of the first PIC chiplet 240A. The first optical fibers 262A can be single mode fibers, for example. The second FAU 260B, which has one or more second optical fibers 262B and a second holder 264B, is attached (e.g., edge coupled) with a planar facet formed in part by the second PIC chiplet 240B and the side face 222 of the EIC 220, e.g., in a similar manner as the first FAU 260A is coupled with the first PIC chiplet 240A and the EIC 220.

In one or more examples, the electro-optical device 200 can be implemented into an optical transceiver, as noted above. In such examples, the first PIC chiplet 240A can be a receiver PIC chiplet and the second PIC chiplet 240B can be a transmitter PIC chiplet. That is, the first PIC chiplet 240A can include optical features (e.g., a photodetector) for receiving optical signals from the first optical fibers 262A and converting them into electrical signals before routing them to the EIC 220, and the second PIC chiplet 240B can include optical features (e.g., a modulator) for converting electrical signals received from the EIC 220 into optical signals and then transmitting them by way of the second optical fibers 262B. In this regard, the electro-optical device 200 can include PIC chiplets that are dedicated to receiver and transmitter functionality. In one or more examples, with the PIC chiplets having dedicated functionality, the area of the first PIC chiplet 240A can be at least six times smaller than the area of the EIC 220, with the areas being measured in an XY plane, or rather, as viewed along the Z-direction as in FIG. 2A. Similarly, in one or more examples, the area of the second PIC chiplet 240B can be at least six times smaller than the area of the EIC 220, with the areas being measured in an XY plane, or rather, as viewed along the Z-direction as in FIG. 2A.

The first and second PIC chiplets 240A, 240B can be bonded face-to-face with the EIC 220, e.g., by way of hybrid bonds 204, such as metal-to-metal, oxide-to-oxide hybrid bonds. In FIG. 2B, an active side 224 of the EIC 220 is arranged face up and an active side 244A of the first PIC chiplet 240A is arranged face down and bonded to the EIC 220. The active side 244A of the first PIC chiplet 240A is opposite a back side 246A of the first PIC chiplet 240A, with the back side 246A being non-active. An active side of the second PIC chiplet 240B can likewise be arranged face down and bonded to the active side 224 of the EIC 220.

In the illustrated embodiment of FIGS. 2A and 2B, the EIC 220 has a plurality of through-silicon vias (TSVs), or TSVs 232. In FIGS. 2A and 2B, as noted above, the active side 224 of the EIC 220 is face up and bonded face-to-face with the first and second PIC chiplets 240A, 240B, while the active sides of the first and second PIC chiplets 240A, 240B are face down. The TSVs 232 connect the active side 224 of the EIC 220 with a back side 226 (or non-active side) of the EIC 220. In this way, electrical signals as well as power and ground can travel between the first and second PIC chiplets 240A, 240B and the back side 226 of the EIC 220 through the TSVs 232. The bottom ends of the TSVs 232 can be electrically coupled with the substrate 210 by one or more solder bumps 214, for example.

In one or more further examples, the active side 224 of the EIC 220 can be face down and flip-chip bonded to the substrate 210. In such examples, the TSVs 232 can electrically couple or interconnect the active side 224 of the EIC 220 with the first and second PIC chiplets 240A, 240B, which are both bonded face-to-face with the back side 226 of the EIC 220.

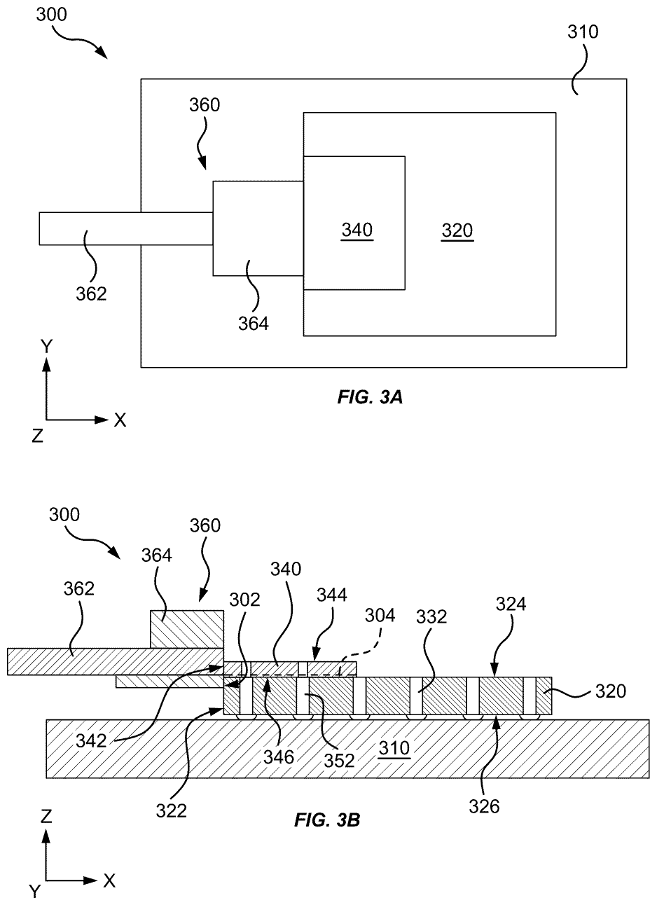

FIGS. 3A and 3B are schematic views of an electro-optical device 300 according to one or more aspects of the present disclosure. FIG. 3A is a schematic top plan view and FIG. 3B is a schematic side cross-sectional view of the electro-optical device 300.

The electro-optical device 300 has a substrate 310, an EIC 320, a PIC chiplet 340, and an FAU 360 having an optical fiber 362 and a holder 364. The FAU 360 is attached to a planar facet 302 provided in part by a side face 342 of the PIC chiplet 340 and in part by a side face 322 of the EIC 320. Further, for the embodiment of FIGS. 3A and 3B, the EIC 320 has an active side 324 and a back side 326, and the PIC chiplet 340 has an active side 344 and a back side 346. As shown in FIG. 3B, the back side 346 of the PIC chiplet 340 is bonded face-to-face with the active side 324 of the EIC 320 while the active side 344 of the PIC chiplet 340 is arranged face up. The back side 346 of the PIC chiplet 340 can be bonded to the EIC 320, e.g., by way of a hybrid bond 304, such as a metal-to-metal, oxide-to-oxide hybrid bond. In alternative examples, the back side 346 of the PIC chiplet 340 can be bonded face-to-face with the back side 326 in examples in which the EIC 320 is flipped.

In addition, in the embodiment of FIGS. 3A and 3B, the EIC 320 has a plurality of TSVs 332, much like the EIC 220 of FIGS. 2A and 2B. Furthermore, as shown in FIG. 3B, the PIC chiplet 340 has a plurality of TSVs 352. The TSVs 352 of the PIC chiplet 340 can be coupled with respective ones of the TSVs 332 of the EIC 320 and can connect the EIC 320 with the active side 344 of the PIC chiplet 340, which, as noted above, is arranged face up in the embodiment of FIGS. 3A and 3B. This architectural arrangement can allow for the PIC chiplet 340 to be face up (or facing away from the EIC 320) with additional clearance and vision feature access for fiber attach.

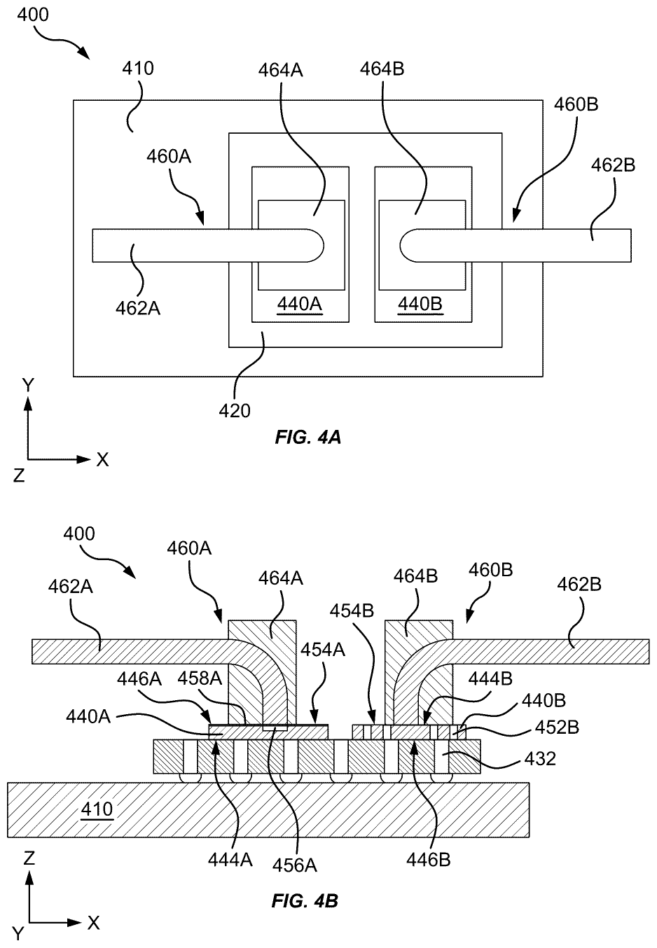

FIGS. 4A and 4B are schematic views of an electro-optical device 400 according to one or more aspects of the present disclosure. FIG. 4A is a schematic top plan view and FIG. 4B is a schematic side cross-sectional view of the electro-optical device 400. The electro-optical device 400 can allow for an FAU to be surface coupled to a PIC chiplet (rather than edged coupled as in FIGS. 1A, 1B, 2A, 2B, 3A, 3B), with the FAU being in direct contact with the active surface of the PIC chiplet or alternatively coupled through the silicon bulk of the PIC chiplet.

The electro-optical device 400 has a substrate 410, an EIC 420, first and second PIC chiplets 440A, 440B, and first and second FAUs 460A, 460B, which are respectively coupled with the first and second PIC chiplets 440A, 440B. The first FAU 460A has a first optical fiber 462A and a first holder 464A, and the second FAU 460B has a second optical fiber 462B and a second holder 464B.

As shown in FIG. 4B, the optical I/O of the first and second PIC chiplets 440A, 440B can be integrated into their respective top surfaces 454A, 454B, e.g., using diffractive grating couplers. Accordingly, the first and second optical fibers 462A, 462B can each transition respectively from a horizontal orientation to a vertical orientation, with the first and second holders 464A, 464B holding and supporting the first and second optical fibers 462A, 462B in their respective vertical orientations to couple with their respective first and second PIC chiplets 440A, 440B. Such features can allow the first and second PIC chiplets 440A, 440B to be placed anywhere on the EIC 420, with the side faces of the first and second PIC chiplets 440A, 440B not necessarily aligned with the side faces of the EIC 420.

In one or more examples, an active side of at least one PIC chiplet can be bonded face down on the EIC 420 and a back side of the PIC chiplet can have a diffractive grating coupler for optical coupling with an optical fiber of an FAU. In this manner, an optical signal can travel through the bulk or thickness of the PIC chiplet between the optical fiber and the active side of the PIC chiplet. In FIG. 4B, for example, the first PIC chiplet 440A has an active side 444A and an opposing back side 446A. The active side 444A of the first PIC chiplet 440A is bonded (e.g., hybrid bonded, such as with a metal-to-metal, oxide-to-oxide hybrid bond) face down on the EIC 420. The back side 446A, which is face up and facing toward the first optical fiber 462A, has a diffractive grating coupler 456A for optical coupling with the first optical fiber 462A. In such examples, the back side 446A of the first PIC chiplet 440A can have an anti-reflective coating 458A. Optical signals can travel between the first optical fiber 462A and the active side 444A of the first PIC chiplet 440A through the bulk or thickness of the first PIC chiplet 440A. The first PIC chiplet 440A can be formed of silicon and can have a thickness of 50 microns or less, for example. In at least one example, the first PIC chiplet 440A can include a focusing optical element (e.g., a lens) to direct or focus optical signals between the first optical fiber 462A and the active side 444A of the first PIC chiplet 440A.

In one or more examples, the back side of at least one PIC chiplet can be bonded to the EIC 420 and the active side can be face up, or rather, facing away from the EIC 420. The PIC chiplet can have TSVs that connect the active side of the PIC chiplet with the EIC 420. The active side of the PIC chiplet can provide an optical coupling facet for coupling with an optical fiber of an FAU. In FIG. 4B, for example, the second PIC chiplet 440B has an active side 444B and an opposing back side 446B. The active side 444B is face up and faces away from the EIC 420. The active side 444B faces the second optical fiber 462B. The second PIC chiplet 440B has TSVs 452B that connect the active side 444B of the second PIC chiplet 440B with the EIC 420. The TSVs 452B can be electrically coupled with TSVs 432 of the EIC 420. The active side 444B of the second PIC chiplet 440B can provide an optical coupling facet for coupling with the second optical fiber 462B of the second FAU 460B.

In one or more examples, each of the PIC chiplets of the electro-optical device 400 can be configured in a same or similar manner as the first PIC chiplet 440A. In one or more examples, each of the PIC chiplets of the electro-optical device 400 can be configured in a same or similar manner as the second PIC chiplet 440B. In one or more other examples, the PIC chiplets of the electro-optical device 400 can include a combination of first and second PIC chiplets 440A, 440B.

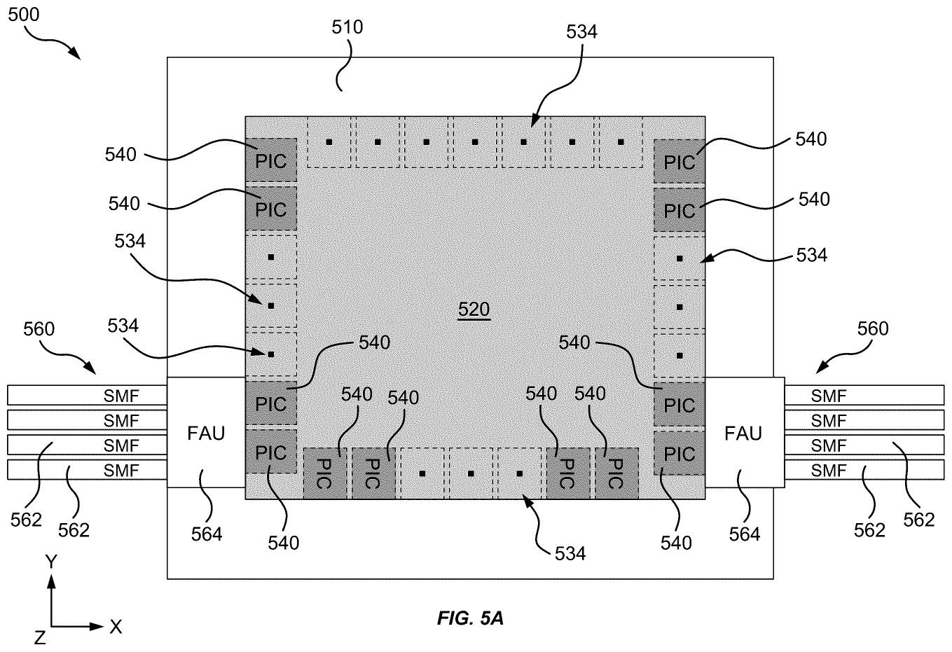

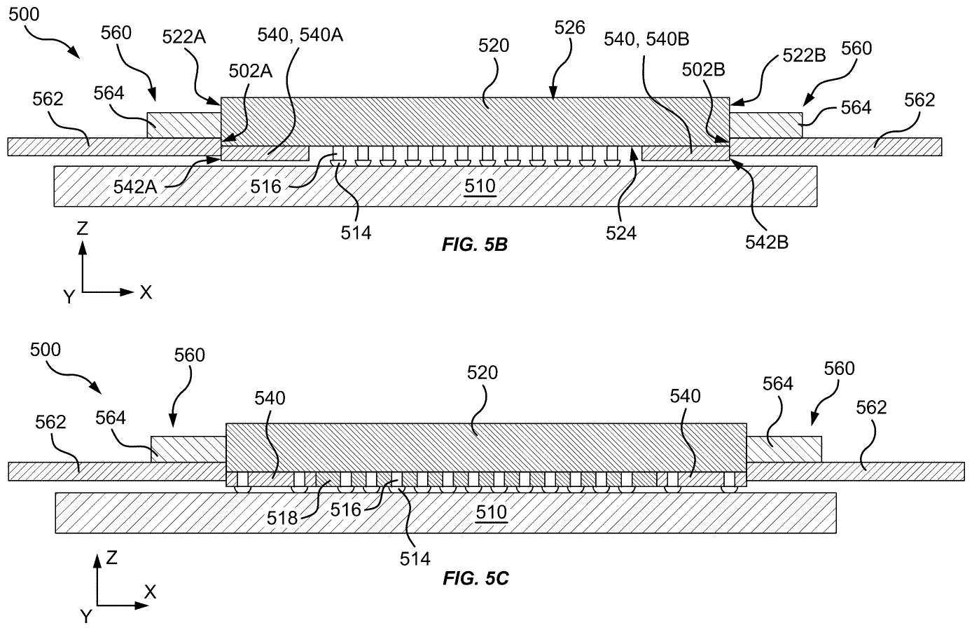

FIGS. 5A and 5B are schematic views of an electro-optical device 500 according to one or more aspects of the present disclosure. FIG. 5A is a schematic top plan view and FIG. 5B is a schematic side cross-sectional view of the electro-optical device 500. As will be explained further below, the electro-optical device 500 can provide a solution to address demands for higher bisection bandwidth and optical compute architectures. The electro-optical device 500 includes topical and intimate integration of compact, efficient silicon photonic chiplets on an EIC, such as an XPU or high performance ASIC.

As illustrated in FIGS. 5A and 5B, the electro-optical device 500 has a substrate 510, an EIC 520, a plurality of PIC chiplets 540, and a plurality of FAUs 560, which are respectively coupled with one or more of the PIC chiplets 540. The EIC 520 is shown transparent in FIG. 5A for illustrative purposes, namely to show the arrangement of the PIC chiplets 540 relative to the EIC 520. The EIC 520 can be an ASIC or XPU, for example. The FAUs 560 each have one or more optical fibers 562 held and supported by a holder 564. The PIC chiplets 540 can be bonded (e.g., by a hybrid bond) to the EIC 520, such as to a bottom surface of the EIC 520 as depicted in FIG. 5B. In one or more examples, the PIC chiplets 540 can be attached simultaneously to the EIC 520 with die-to-wafer hybrid bonding, such as metal-to-metal, oxide-to-oxide hybrid bonding. The area of each PIC chiplets 540 can be relatively small compared to the area of the EIC 520, such as less than one eightieth of the area of the EIC 520, taken along the XY plane.

In one or more examples, the EIC 520 (e.g., XPU) can have a plurality of optical ports 534, e.g., arranged along an outer periphery or perimeter of the EIC 520 as shown in FIG. 5A. The plurality of PIC chiplets 540 can be coupled with respective ones of the optical ports 534 in a face-to-face manner. That is, the PIC chiplets 540 are hybrid integrated in a face-to-face manner directly to I/O (driver/receiver) circuits on the EIC 520, which is an XPU in such examples. The PIC chiplets 540 can be sized so that a given PIC chiplet is no larger in area (e.g., in an XY plane) than an input/output block to which the given PIC chiplet is coupled. In at least one example, at least one of the PIC chiplets 540 has a thickness of less than or equal to 100 microns (e.g., along the Z-direction).

The PIC chiplets 540 can be bonded to the EIC 520 so that the FAUs 560 attach to respective planar facets provided in part by one or more of the PIC chiplets 540 and in part by the EIC 220, as shown in FIG. 5B. Specifically, as illustrated in FIG. 5B, a first PIC chiplet 540A of the PIC chiplets 540 can have a first side face 542A that provides an optical coupling facet of the first PIC chiplet 540A. The first side face 542A of the first PIC chiplet 540A is coplanar with a first side face 522A of the EIC 520. The first side face 542A of the first PIC chiplet 540A and the first side face 522A of the EIC 520 collectively form a planar facet 502A to which one of the FAU 560 is attached. Accordingly, optical edge coupling of the FAU 560 is provided at the planar facet 502A. As further illustrated in FIG. 5B, a second PIC chiplet 540B of the PIC chiplets 540 can have a second side face 542B that provides an optical coupling facet of the second PIC chiplet 540B. The second side face 542B is coplanar with a second side face 522B of the EIC 520. The second side face 542B is opposite the first side face 522A. The second side face 542B of the second PIC chiplet 540B and the second side face 522B of the EIC 520 collectively form a planar facet 502B to which one of the FAU 560 is attached. Accordingly, optical edge coupling of the FAU 560 is provided at the planar facet 502B. As will be appreciated by viewing FIG. 5A, optical edge couplings can be provided along the perimeter of the EIC 520.

In one or more examples, the PIC chiplets 540 are juxtaposed with an array of conductive interconnects on the EIC 520, or XPU in such examples. The EIC 520 can have an active side 524 and a back side 526 arranged opposite the active side 524. The active side 524 can be arranged face down, or rather, facing toward the substrate 510. The PIC chiplets 540 can be hybrid bonded to the active side 524 of the EIC 520, e.g., in locations corresponding to the optical ports 534 of the EIC 520. The PIC chiplets 540 can be juxtaposed (i.e., arranged side-by-side) with interconnects 516 that extend between the EIC 520 and the substrate 510. The interconnects 516 can be connected to the substrate 510, e.g., by way of solder bumps 514. In one or more examples, the interconnects 516 can be high aspect ratio conductive interconnects, such as solder-capped copper pillars.

In one or more further examples, as shown in the side cross-sectional view of the electro-optical device 500 in FIG. 5C, a filler 518 (e.g., an epoxy mold compound (EMC)/silica filling) can encapsulate the array of interconnects 516. The filler 518 can have a thickness at least equal to a thickness of the PIC chiplets 540, e.g., as shown in FIG. 5C. The filler 518 can support the interconnects 516 and the PIC chiplets 540 and can provide a uniform thickness of the package, e.g., along the Z-direction.

In one or more examples, the electro-optical device 500 can be fabricated by hybrid bonding the PIC chiplets 540 to the EIC 520 in a wafer-level process. Next, the integrated wafer can go through a bumping process to deposit the area array of interconnects 516. Finally, the bumped wafer can be diced to yield or singulate the integrated EIC 520. In some aspects, the filler 518 can be added to encapsulate the front side of the wafer followed by via formation, plating, and bumping.

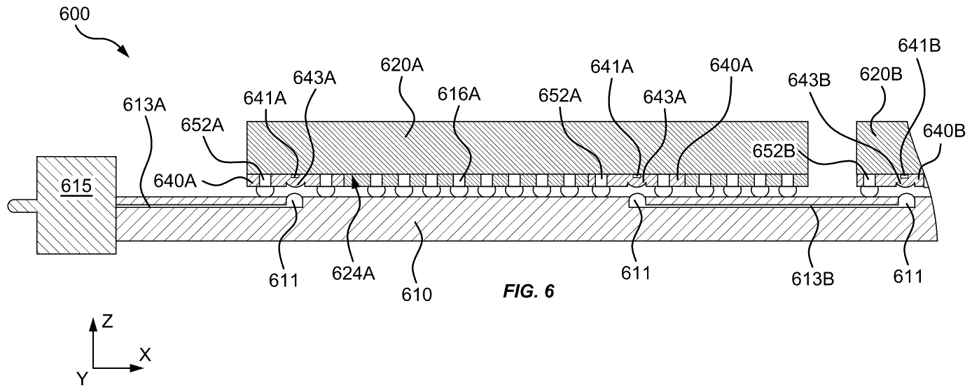

FIG. 6 is schematic side cross-sectional view of an electro-optical device 600 according to one or more aspects of the present disclosure. As described further below, the electro-optical device 600 includes an optically-enabled substrate (or optically-enabled PCB) that provides optical pathways between devices mounted on the substrate as well as to devices offboard of the substrate. For instance, the optically-enabled substrate can enable optical coupling between neighboring EICs both mounted to the substrate or to an offboard device via pluggable edge connectors of the optically-enabled substrate. Moreover, the optically-enabled substrate allows for one or more EICs to be placed freely on the optical substrate, thus providing mounting location flexibility.

As depicted in FIG. 6, the electro-optical device 600 includes an optically-enabled substrate 610 (e.g., an optically-enabled PCB), a plurality of EICs, and PIC chiplets coupled with the EICs. Particularly, the electro-optical device 600 includes a first EIC 620A (e.g., a first XPU) and a second EIC 620B (e.g., a second XPU) spaced from the first EIC 620A, e.g., along the X-direction. A plurality of PIC chiplets 640A are hybrid bonded to an active side 624A of the first EIC 620A and juxtaposed with an array of interconnects 616A that extend between the first EIC 620A and the optically-enabled substrate 610. The PIC chiplets 640A can each include TSVs 652A, which can electrically couple electrical components of the optically-enabled substrate 610 and the first EIC 620A. Similarly, a plurality of PIC chiplets 640B are hybrid bonded to an active side of the second EIC 620B. The PIC chiplets 640B can each include TSVs 652B, which can electrically couple electrical components of the optically-enabled substrate 610 and the second EIC 620B.

In one or more examples, one or more of the PIC chiplets 640A, 640B can include optical elements that enable optical signals to travel between the PIC chiplets 640A and the optically-enabled substrate 610 and between the PIC chiplets 640B and the optically-enabled substrate 610. For instance, the PIC chiplets 640A can each include a diffractive optical element 641A (e.g., a grating coupler) arranged to deflect an optical signal out of plane and downward through a lens 643A facing an optical coupler 611 of the optically-enabled substrate 610. The optical couplers 611 can each be optically aligned with a respective one of the lenses 643A. In this way, optical signals can travel along the Z-direction between the lenses 643A and the optical couplers 611 to which they are aligned. The PIC chiplets 640B of the second EIC 620B can each include a diffractive optical element 641B (e.g., a grating coupler) arranged to deflect an optical signal out of plane and downward through a lens 643B facing one of the optical couplers 611 of the optically-enabled substrate 610. The lenses 643A, 643B, or beam forming optical elements, integrated into their respective PIC chiplets 640A, 640B can collimate the beam of an optical signal, which can advantageously relax coupling tolerances with the optical couplers 611 of the optically-enabled substrate 610.

In one or more examples, the optically-enabled substrate 610 can include a network of embedded optical waveguides that can enable optical signal travel through the optically-enabled substrate 610, e.g., from one EIC to another, from one EIC to an optical connector, etc. As shown in FIG. 6, for example, the optically-enabled substrate 610 can include a first substrate waveguide 613A that optically couples one of the optical couplers 611 with an optical receptacle 615 arranged at an edge or side face of the optically-enabled substrate 610. In this way, the optically-enabled substrate 610 allows the first EIC 620A to optically connect to devices off of the optically-enabled substrate 610 via a pluggable edge connector connected to the optical receptacle 615. The optically-enabled substrate 610 can also include a second substrate waveguide 613B that optically couples one of the optical couplers 611 optically aligned with one of the lenses 643A with another optical coupler 611 aligned with one of the lenses 643B of the second EIC 620B. In this regard, the neighboring first and second EICs 620A, 620B can be optically coupled with one another.

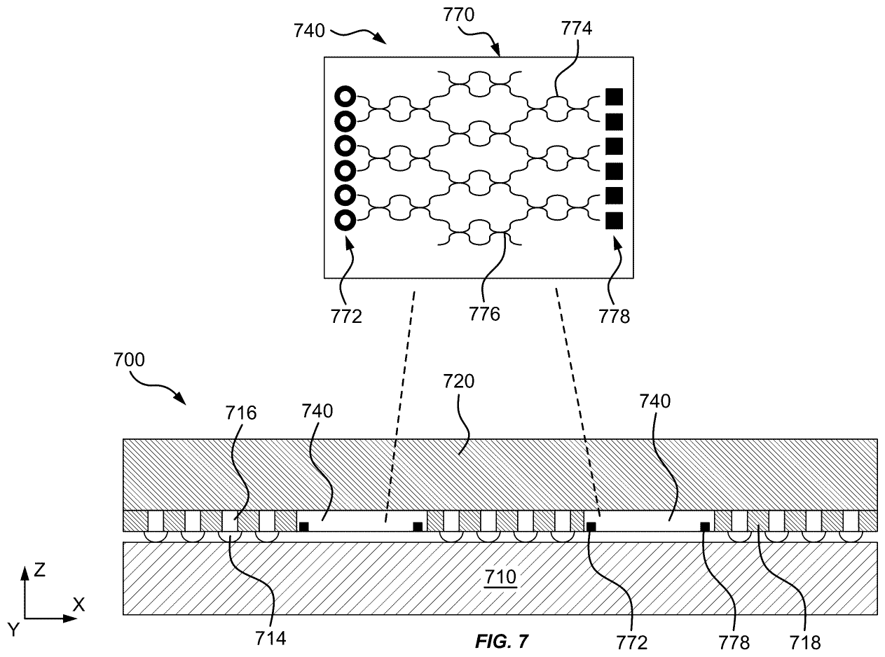

FIG. 7 is schematic side cross-sectional view of an electro-optical device 700 according to one or more aspects of the present disclosure. The electro-optical device 700 of FIG. 7 can be useful for artificial intelligence applications and can enable a hybrid tensor processing unit (TPU), or “hybrid TPU” arranged to optically handle multiply-accumulate (MAC) operations. In this regard, the hybrid TPU can be used for neural network machine learning applications, including large language models (LLM). PIC chiplets can provide the optical functionality to perform MAC operations, and can each include integrated light sources and detectors, which can make the PIC chiplet self-sufficient without optical inputs/outputs. The integrated light sources and the detectors can be electrically driven by the TPU.

As shown in FIG. 7, the electro-optical device 700 includes a substrate 710 (e.g., a PCB), an EIC 720 (e.g., a TPU), and one or more PIC chiplets 740 bonded to the EIC 720. For instance, the PIC chiplets 740 can be hybrid bonded to the EIC 720, e.g., by way of a metal-to-metal, oxide-to-oxide hybrid bond. Interconnects 716 and solder bumps 714 can electrically couple the EIC 720 with the substrate 710. A filler 718 (e.g., an EMC/silica filling) can encapsulate the array of interconnects 716 and can support the PIC chiplets 740.

In one or more examples, the electro-optical device 700 can be configured as a hybrid TPU. Specifically, at least one of the PIC chiplets 740 can provide on-chip, optical functionality for performing MAC operations. As shown in FIG. 7, at least one of the PIC chiplets 740 can include an on-chip network 770, such as a neural network having an input layer, one or more hidden layers that include a plurality of interconnected nodes, and an output layer. The input layer of the PIC chiplet 740 has integrated lasers 772, or electrical-to-optical converters, that provide light inputs to the plurality of interconnected nodes. The integrated lasers 772 can convert electrical signals received from the EIC 720 into optical signals. Each hidden layer can include a set of nodes 774 (e.g., optical interferometers) interconnected with nodes of other layers by light paths 776. The light or optical signals output by the integrated lasers 772 can travel through the hidden layers, where weights, unity rotations, and/or activation functions are applied to the data of the optical signals at the nodes 774. The output layer of the PIC chiplet 740 has integrated photodetectors 778, or optical-to-electrical converters. The integrated photodetectors 778 can receive the light outputs from the nodes of the last hidden layer, and can convert the received optical signals to electrical signals, which can then be routed to the EIC 720. The integrated lasers 772 and the integrated photodetectors 778 can be integrated onto a substrate of the PIC chiplet (e.g., a silicon substrate) and electrically driven by the EIC 720.

Accordingly, computational intensive MAC operations can advantageously be offloaded from the EIC 720 to the PIC chiplets 740 and executed, at least in part, optically by the on-chip optical elements. The MAC operations can be executed efficiently by using the optical elements of the PIC chiplets 740, e.g., with lower power, fewer clock cycles, and/or lower latency in the optical domain than in the electrical domain. Offloading the MAC operations can also free up the computing resources of the EIC 720 for other tasks, among other benefits. In one or more examples, no light need be input or output from the PIC chiplets 740 to handle the MAC operations. In this regard, the PIC chiplets 740 can be optically self-sufficient.

The features of any of the electro-optical devices disclosed herein (i.e., devices 100, 200, 300, 400, 500, 600, and 700) can be combinable with any other disclosed electro-optical device.

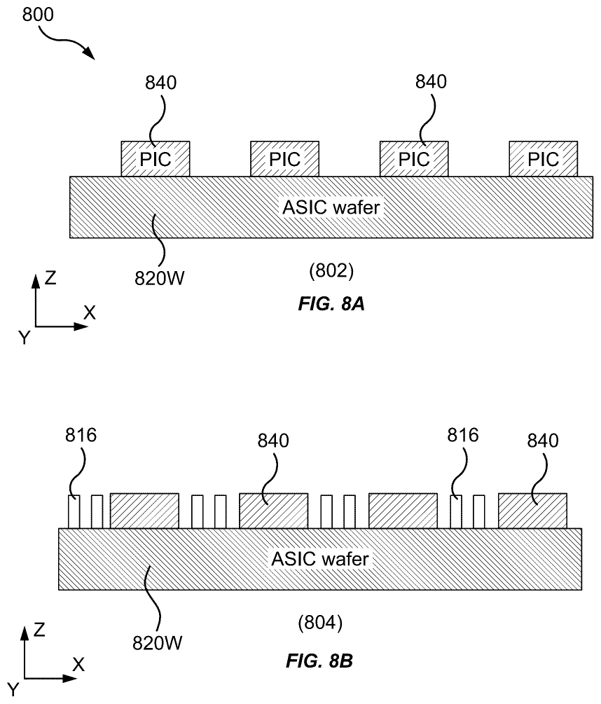

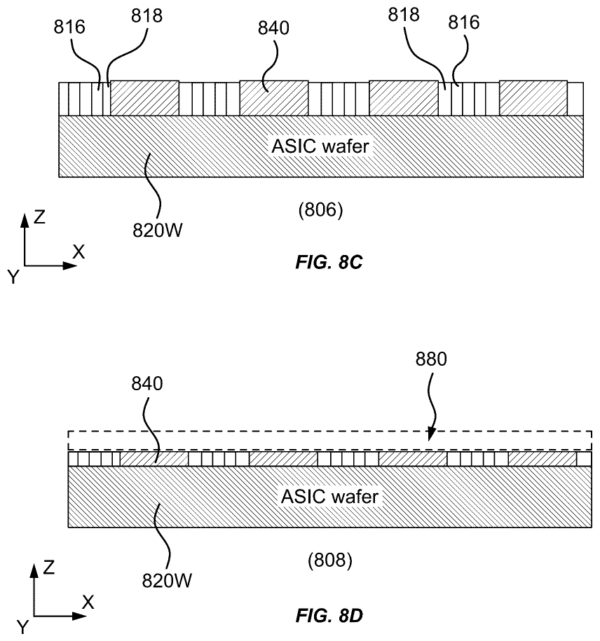

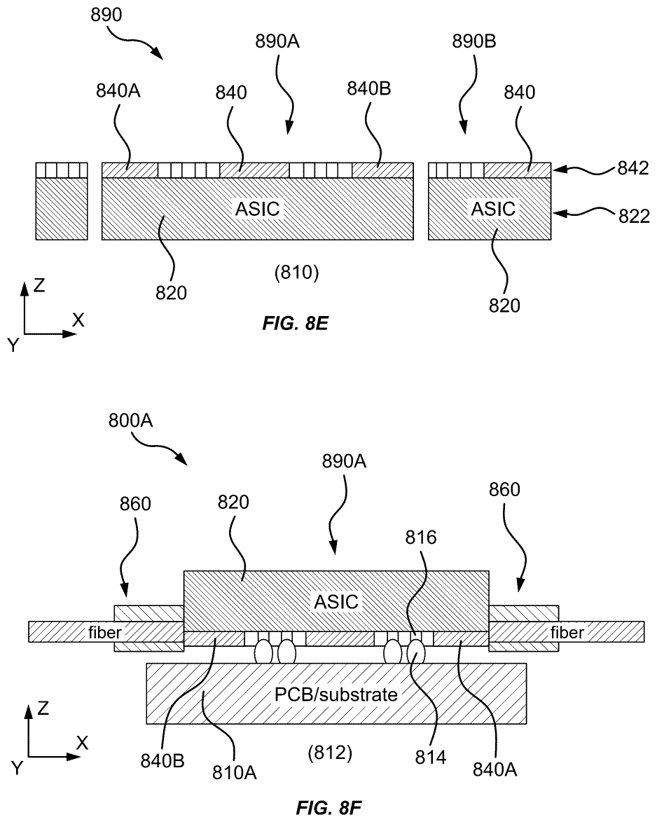

FIGS. 8A through 8F provides a flow diagram for a method 800 of fabricating an electro-optical device, according to one or more aspects of the present disclosure. For instance, the method 800 of FIGS. 8A-8F can be utilized to fabricate a co-sided or multisided electro-optical device.

At 802, the method 800 can include bonding PIC chiplets to an EIC wafer to form, at least in part, a die-wafer assembly. For instance, as shown in FIG. 8A, a plurality of PIC chiplets 840 can be bonded to an EIC wafer 820W. In some implementations, the PIC chiplets 840 can be hybrid bonded to the EIC wafer 820W, such as by a metal-to-metal, oxide-to-oxide hybrid bond. In at least one implementation, the PIC chiplets 840 can be bonded to the EIC wafer 820W simultaneously or in a single bonding process.

At 804, the method 800 can include forming interconnects (e.g., copper pillars) on the EIC wafer, with the copper pillars being juxtaposed with the PIC chiplets. For instance, as shown in FIG. 8B, a plurality of interconnects 816 can be formed on the EIC wafer 820W to add to the die-wafer assembly. The interconnects 816 can be formed on the same surface to which the PIC chiplets 840 are bonded, and can be grown or formed between or juxtaposed with the PIC chiplets 840. The interconnects 816 can be formed to have the same or substantially the same height as the PIC chiplets 840, e.g., along the Z-direction. A plurality of the interconnects 816 can be formed between each of the PIC chiplets 840.

At 806, the method 800 can include backfilling the interconnects with a fill material. For instance, as depicted in FIG. 8C, a filler 818 can be filled in between the PIC chiplets 840 and the interconnects 816 to further add to the wafer-die assembly. The filler 818 can be an EMC or silica, for example. The filler 818 can be backfilled so as to have the same or substantially the same height as the PIC chiplets 840 and the interconnects 816, e.g., along the Z-direction.

At 808, the method 800 can include machining the PIC chiplets and backfilled interconnects of the die-wafer assembly. For instance, as illustrated in FIG. 8D, the PIC chiplets 840 and interconnects 816 backfilled with the filler 818 can be machined so that the thickness of the PIC chiplets 840, interconnects 816, and filler 818 are reduced, e.g., along the Z-direction. In this regard, a section 880 of the die-wafer assembly can be removed. In some implementations, chemical mechanical polishing can be utilized to machine the die-wafer assembly. As shown in FIG. 8D, the die-wafer assembly can be machined so that PIC chiplets 840, the interconnects 816, and the filler 818 has the same or substantially the same height, e.g., along the Z-direction. In at least some implementations, the height or thickness of the PIC chiplets 840, interconnects 816, and filler 818 can be less than or equal to 50 microns. The uniform thickness of the die-wafer assembly can advantageously facilitate dicing of the die-wafer assembly during a singulation process.

At 810, the method 800 can include singulating the EIC wafer to form singulated units, with each of the singulated units having one or more of the PIC chiplets, at least one of the interconnects, and a portion of the EIC wafer. For instance, with reference to FIG. 8E, the EIC wafer 820W can be singulated (e.g., mechanically diced) so as to form singulated units 890. Each singluated unit 890 can include one or more of the PIC chiplets 840, at least one of the interconnects 816 (backfilled with the filler 818), and a portion of the EIC wafer 820W, represented at 810 in FIG. 8E as EICs 820. In FIG. 8E, for example, a first singulated unit 890A is depicted having a plurality of PIC chiplets 840, backfilled interconnects 816 between the PIC chiplets 840, and an EIC 820 (or a portion of the EIC wafer 820W). Further, in FIG. 8E, a second singulated unit 890B is depicted having one of the PIC chiplets 840, backfilled interconnects 816, and an EIC 820 (or a portion of the EIC wafer 820W).

In some implementations, in singulating the EIC wafer 820W at 810, at least one of the singulated units 890 can be singulated so that an edge face, or side face 842, is coplanar with the edge face, or side face 822, of the EIC 820. For instance, in FIG. 8E, the second singulated unit 890B has a side face 842 that is coplanar with a side face 822 of the EIC 820, collectively forming a planar facet to which an FAU can be attached or edge coupled. In some implementations, in singulating the EIC wafer 820W at 810, at least two of the singulated units 890 can be singulated so that, for each of the at least two singulated units 890, an edge face of a PIC chiplet is coplanar with an edge face of an EIC to which the PIC chiplet is bonded. For instance, in FIG. 8E, the first singulated unit 890A has a first PIC chiplet 840A and a second PIC chiplet 840B, which each have side faces (or edge faces) that are coplanar with respective side faces (or respective edge faces) of the EIC 820. In this way, respective FAUs can be edge coupled or attached to these planar coupling facets. In one or more examples, the coplanar side faces 822, 842 can be formed in a single dice pass. That is, the side faces 822, 842 can be formed simultaneously.

At 812, the method 800 can include attaching one or more FAUs to at least one of the singulated units, e.g., to form a co-sided or multisided electro-optical device. For instance, in FIG. 8F, two FAUs 860 are shown edge coupled to the planar coupling facets of the first singulated unit 890A. Moreover, solder bumps 814 have been formed to electrically connect the interconnects 816 with a substrate 810A (e.g., a PCB), which can electrically couple the EIC 820 with the substrate 810A. Accordingly, an electro-optical device 800A can be formed according to the method 800.

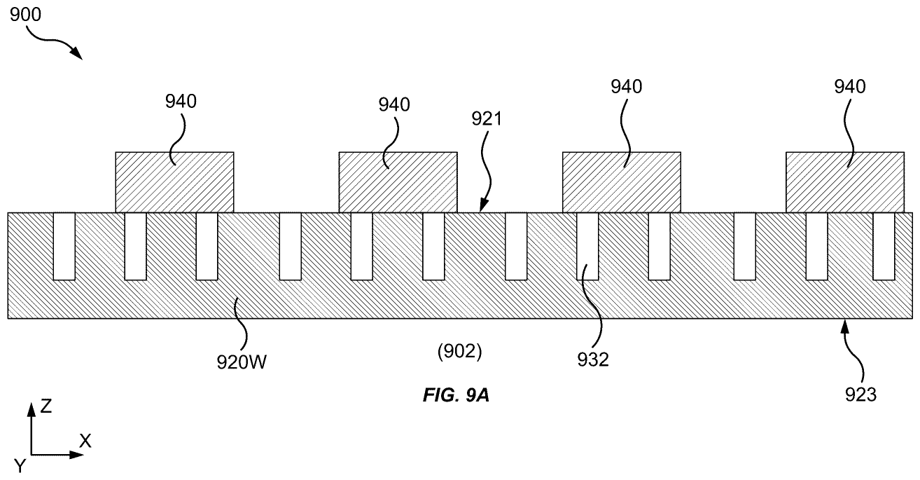

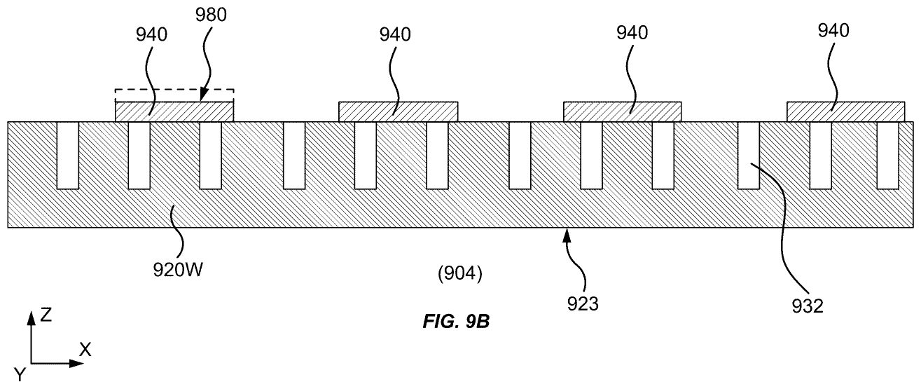

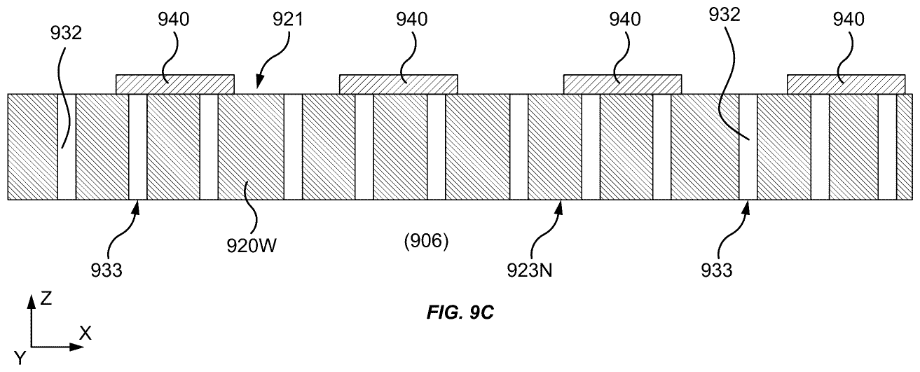

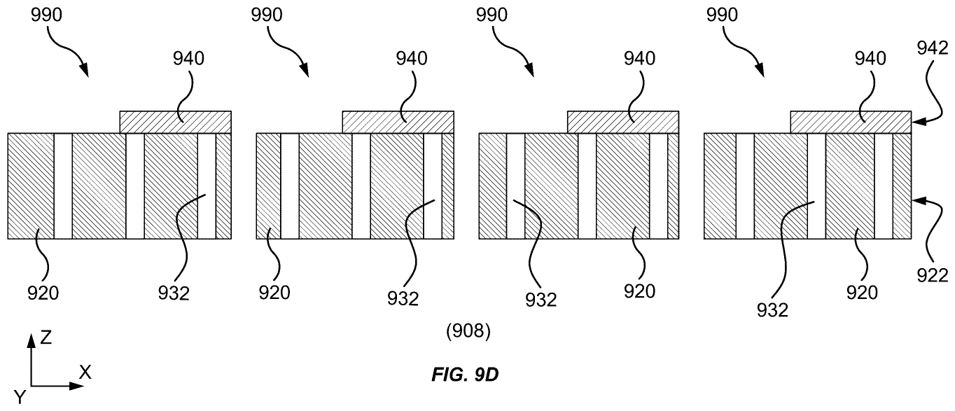

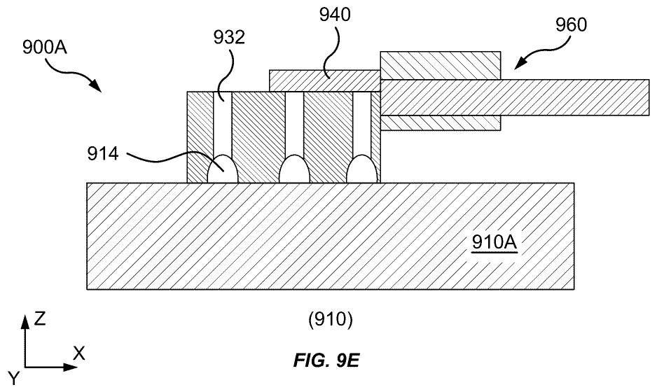

FIGS. 9A through 9E provides a flow diagram for a method 900 of fabricating a TSV-enabled electro-optical device, according to one or more aspects of the present disclosure.

At 902, the method 900 can include bonding PIC chiplets to a first side of an EIC wafer to form, at least in part, a die-wafer assembly. The EIC wafer has TSVs. For instance, as shown in FIG. 9A, a plurality of PIC chiplets 940 can be bonded to a first side 921 of an EIC wafer 920W having TSVs 932. The TSVs can extend from the first side 921 of the EIC wafer 920W a distance along the Z-direction (e.g., at least half the thickness of the EIC wafer 920W along the Z-direction), but not necessarily to a second side 923 of the EIC wafer 920W. The first side 921 opposes the second side 923. In some implementations, the PIC chiplets 940 can be hybrid bonded to the EIC wafer 920W, such as by a metal-to-metal, oxide-to-oxide hybrid bond. In at least one implementation, the PIC chiplets 940 can be bonded to the EIC wafer 920W simultaneously or in a single bonding process.

At 904, the method 900 can include reducing a thickness of the PIC chiplets. For instance, as illustrated in FIG. 9B, the PIC chiplets 940 can be machined so that the PIC chiplets 940 are reduced in thickness, e.g., along the Z-direction. In this regard, a section 980 of each of the PIC chiplets 940 can be removed. In some implementations, chemical mechanical polishing can be utilized to machine the PIC chiplets 940. In at least some implementations, the height or thickness of the PIC chiplets can be less than or equal to 50 microns.

At 906, the method 900 can include machining a second side of the EIC to reveal the TSVs, the second side being opposite the first side. For instance, as illustrated in FIG. 9C, the second side 923 of the EIC wafer 920W can be machined so that the TSVs 932 are revealed. That is, the EIC wafer 920W is machined so that the ends 933 of the TSVs 932 are revealed, as depicted at 906 in FIG. 9C. In this way, a new second side 923N of the EIC wafer 920W is formed and a thickness of the EIC wafer 920W is removed. Accordingly, in performing 904 and 906, the PIC chiplets 940 and the EIC wafer 920W are thinned down. In some implementations, chemical mechanical polishing can be utilized to machine the EIC wafer 920W so as to reveal the ends 933 of the TSVs 932.

At 908, the method 900 can include singulating the EIC wafer to form singulated units, with each of the singulated units having one or more of the PIC chiplets, at least one of the TSVs, and a portion of the EIC wafer. For instance, with reference to FIG. 9D, the EIC wafer 920W can be singulated (e.g., mechanically diced) so as to form singulated units 990. Each singluated unit 990 can include one or more of the PIC chiplets 940, at least one of the TSVs 932, and a portion of the EIC wafer 920W, represented at 908 in FIG. 9D as EICs 920.

In some implementations, in singulating the EIC wafer 920W at 908, at least one of the singulated units 990 can be singulated so that an edge face, or side face 942, is coplanar with the edge face, or side face 922, of the EIC 920. The coplanar side faces 922, 942 can collectively form a planar facet to which an FAU can be attached or edge coupled. In some implementations, at least two or a plurality of the singulated units 990 can include coplanar side faces that collectively form a planar facet to which an FAU can be attached or edge coupled, e.g., as shown in FIG. 9D at 908.

At 910, the method 900 can include attaching one or more FAUs to at least one of the singulated units, e.g., to form an electro-optical device. For instance, in FIG. 9E, an FAU 960 is shown edge coupled to a planar coupling facet of one of the singulated units 990. In addition, solder bumps 914 have been formed to electrically connect the TSVs 932 with a substrate 910A (e.g., a PCB), which can electrically couple the EIC 920 with the substrate 910A. Accordingly, an electro-optical device 900A, which is TSV-enabled, can be formed according to the method 900.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s).

In view of the foregoing, the scope of the present disclosure is determined by the claims that follow.

We claim:

1. An electro-optical device, comprising:
an electrical integrated circuit (EIC);
a photonic integrated circuit (PIC) chiplet bonded face-to-face with the EIC, the PIC chiplet being smaller in size than the EIC; and
a fiber array unit (FAU) having an optical fiber optically coupled with the PIC chiplet.

2. The electro-optical device of claim 1, wherein the EIC has an active side arranged face up and the PIC chiplet has an active side arranged face down, and wherein the PIC chiplet and the EIC are bonded face-to-face with the active side of the EIC bonded to the active side of the PIC chiplet.

3. The electro-optical device of claim 1, wherein the PIC chiplet has optical blocks each having an area, and wherein a total area of the PIC chiplet is not more than twice a total optical block area that is a sum of the areas of the optical blocks, with the total area and the total optical block area both being measured in a direction perpendicular to a plane in which the PIC chiplet is bonded face-to-face with the EIC.

4. The electro-optical device of claim 1, wherein a side face of the PIC chiplet is coplanar with a side face of the EIC, with the side face of the PIC chiplet and the side face of the EIC collectively forming a planar coupling facet to which the FAU is attached.

5. The electro-optical device of claim 1, wherein the PIC chiplet and the EIC are bonded face-to-face with a metal-to-metal, oxide-to-oxide hybrid bond.

6. The electro-optical device of claim 1, wherein the EIC has a plurality of through-silicon vias (TSVs).

7. The electro-optical device of claim 6, wherein an active side of the EIC is face up and bonded face-to-face with the PIC chiplet, and wherein the TSVs electrically connect the active side of the EIC with a back side of the EIC.

8. The electro-optical device of claim 6, wherein an active side of the EIC is face down and flip-chip bonded to a substrate, and wherein the TSVs electrically connect the active side of the EIC with the PIC chiplet, which is bonded face-to-face with a back side of the PIC chiplet.

9. The electro-optical device of claim 1, wherein the PIC chiplet has an active side and a back side, and wherein the back side of the PIC chiplet is bonded face-to-face with the EIC and the active side is arranged face up, and wherein the EIC has a plurality of through-silicon vias (TSVs) and the PIC chiplet has a plurality of TSVs, and wherein the TSVs of the PIC chiplet are coupled with respective ones of the TSVs of the EIC and connect the EIC with the active side of the PIC chiplet.

10. The electro-optical device of claim 1, wherein the PIC chiplet has an active side and a back side opposing the active side, and wherein the active side of the PIC is bonded face down on the EIC and the back side has a diffractive grating coupler for optical coupling with the optical fiber of the FAU.

11. The electro-optical device of claim 1, wherein the PIC chiplet has an active side and a back side opposing the active side, and wherein the back side of the PIC is bonded face down on the EIC and the PIC chiplet has through-silicon vias (TSVs) that connect the active side of the PIC chiplet with the EIC, the active side of the PIC chiplet providing an optical coupling facet for coupling with the optical fiber of the FAU.

12. The electro-optical device of claim 1, wherein the PIC chiplet is one of a plurality of PIC chiplets bonded to the EIC, and wherein the plurality of PIC chiplets are hybrid bonded to an active side of the EIC and juxtaposed with interconnects backfilled with a filler, the interconnects extending between the EIC and a substrate.

13. The electro-optical device of claim 1, wherein the PIC chiplet is one of a plurality of PIC chiplets bonded to the EIC, and wherein the EIC has a plurality of optical ports, and wherein the plurality of PIC chiplets are coupled with respective ones of the optical ports in a face-to-face manner and are no larger than the optical ports to which they are coupled.

14. The electro-optical device of claim 1, further comprising:
an optically-enabled substrate having an optical coupler, and
wherein the PIC chiplet has a diffractive optical element that deflects an optical signal out of plane and downward through a lens facing the optical coupler of the optically-enabled substrate.

15. The electro-optical device of claim 14, wherein the optically-enabled substrate includes an embedded optical waveguide that optically couples the optical coupler with another optical coupler arranged in optical alignment with a second PIC chiplet bonded to a second EIC mounted on the optically-enabled substrate or to an optical receptacle arranged at an edge of the optically-enabled substrate.

16. The electro-optical device of claim 1, wherein the EIC is a high bandwidth memory device.

17. The electro-optical device of claim 1, wherein the electro-optical device is an optical transceiver and the PIC chiplet is one of a plurality of PIC chiplets, with the plurality of PIC chiplets including a receiver PIC chiplet and a transmitter PIC chiplet both bonded face-to-face with the EIC and both having side faces coplanar with a side face of the EIC.

18. An electro-optical device, comprising:
an electrical integrated circuit (EIC); and
a photonic integrated circuit (PIC) chiplet bonded face-to-face with the EIC, the PIC chiplet being smaller in size than the EIC and having an on-chip network, the on-chip network including integrated lasers arranged to provide light inputs to a plurality of interconnected nodes and integrated photodetectors arranged to receive light outputs from the plurality of interconnected nodes.

19. The electro-optical device of claim 18, wherein the on-chip network is a neural network having optical interferometers interconnected by light paths.

20. A method of fabricating an electro-optical device, comprising:
bonding photonic integrated circuit (PIC) chiplets to an electronic integrated circuit (EIC) wafer;
machining the PIC chiplets to reduce a thickness thereof; and
singulating the EIC wafer to form singulated units, with at least one of the singulated units having one or more of the PIC chiplets and a portion of the EIC wafer.
